(19) United States
(12) Patent Application Publication
(10) Pub. No.: US 2009/0160485 A1
(43) Pub. Date: Jun. 25, 2009

(54) Providing Higher-Swing Output Signals When Components Of An Integrated Circuit Are Fabricated Using A Lower-Voltage Process

(75) Inventors: Karthik Rajagopal, Bangalore (IN); Aatmesh, Muzafarpur (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/959,496

(22) Filed: Dec. 19, 2007

(51) Int. Cl. H03K 19/0175

(52) U.S. Cl. 326/80

(57) ABSTRACT

An output block fabricated using a lower-voltage process provides output signals with a higher voltage swing. The output block contains a differential amplifier portion and a hold circuit portion. The differential amplifier portion is activated only when the logic level of an output signal needs to be switched. Once the logic level is switched, the hold circuit portion maintains the logic level. As a result, high switching speeds may be achieved with relatively low power consumption. The circuits of the output block are also designed so that no constituent components are subjected to excessive voltages, thereby providing enhanced reliability.

### BACKGROUND

1. Field of the Technical Disclosure

The present disclosure relates generally to integrated circuit (IC) design, and more specifically to providing output signals with higher signal swing strengths using integrated circuit (IC) components fabricated using lower-voltage processes.

2. Related Art

An integrated circuit (IC) generally contains various types of components such as transistors, resistors, capacitors, etc, which are interconnected according to desired design specification. ICs are generally formed by fabrication, which generally entails depositing various semi-conductor material and interconnecting paths to form the desired components, as is well known in the relevant arts.

Various characteristics of the material thus formed (constituting an IC) define a fabrication process. Such characteristics generally include the material used, the sequence in which the material is deposited, thickness, width, length of the various layers/material, as is well known in the relevant arts.

Such fabrication processes are often tailored for operation of the IC at different power supplies. For example, to operate with a higher voltage power supply, it may be generally required to have material of more thickness, which would enable the components to withstand higher voltages. A fabrication process tailored for a voltage of a specific magnitude is termed as a process of a corresponding voltage. Examples of such different processes include 3.3 V CMOS process, 1.8 V CMOS process etc.

There are often scenarios when an IC is required to provide higher-swing output signals when components of an integrated circuit are fabricated using a lower-voltage process. For example, it may be desirable to implement at least some portions (e.g., a core portion containing the main functional part of the IC or an output block) using a lower voltage process (for advantages such as lower power consumption, reduced area requirements, etc.), while the output signals may need to be provided at a higher voltage level as well (for reasons such as legacy compatibility, to provide stronger signals, etc.).

As is well appreciated, it is generally desirable to fabricate the entire circuit using the same fabrication process (of lower voltage).

Such fabrication may need to be performed to meet various requirements of integrated circuits potentially specific to the environment in which they are deployed.

### BRIEF DESCRIPTION OF THE DRAWINGS

The present invention will be described with reference to the following accompanying drawings, which are described briefly below.

FIG. 1 is a block diagram of an example environment in which several aspects of the present invention can be implemented.

FIG. 2 is a circuit diagram illustrating the details of a portion of an output block implemented according to a prior technique.

FIG. 3 is a block diagram of an output block in an embodiment of the present invention.

FIG. 4A is a diagram of a driver block used in an output block in an embodiment of the present invention.

FIG. 4B is a waveform used to illustrate the operation of an output block in an embodiment of the present invention.

FIG. 5 is a flowchart illustrating the manner in which operation of an output block may be controlled in an embodiment of the present invention.

FIG. 6A is a block diagram of partial internal details of a level shifter and control block used in an output block in an embodiment of the present invention.

FIG. 6B is a timing diagram illustrating the operation of a portion of a level shifter and control block used in an output block in an embodiment of the present invention.

FIG. 7 is circuit diagram of a driver block used in conjunction with the driver block of FIG. 4A, in an embodiment of the present invention.

FIG. 8 is a diagram of partial internal details of a level shifter and control block in used in conjunction with the driver block of FIG. 7, in an embodiment of the present invention.

FIG. 9 is a block diagram of a device/system in an output block implemented according to several aspects of the present invention may be incorporated.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

Overview

An output block provided according to an aspect of the present invention is fabricated using a lower-voltage process, but provides output signals with a higher voltage swing. In an embodiment, the output block contains a differential amplifier portion and a hold circuit portion. The differential amplifier portion is activated only when the logic level of an output signal needs to be switched. Once the logic level is switched, the hold circuit portion maintains the logic level. As a result, high switching speeds may be achieved with relatively low power consumption. The circuits of the output block are also designed so that no constituent components are subjected to excessive voltages, thereby providing enhanced reliability.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

2. Example Environment

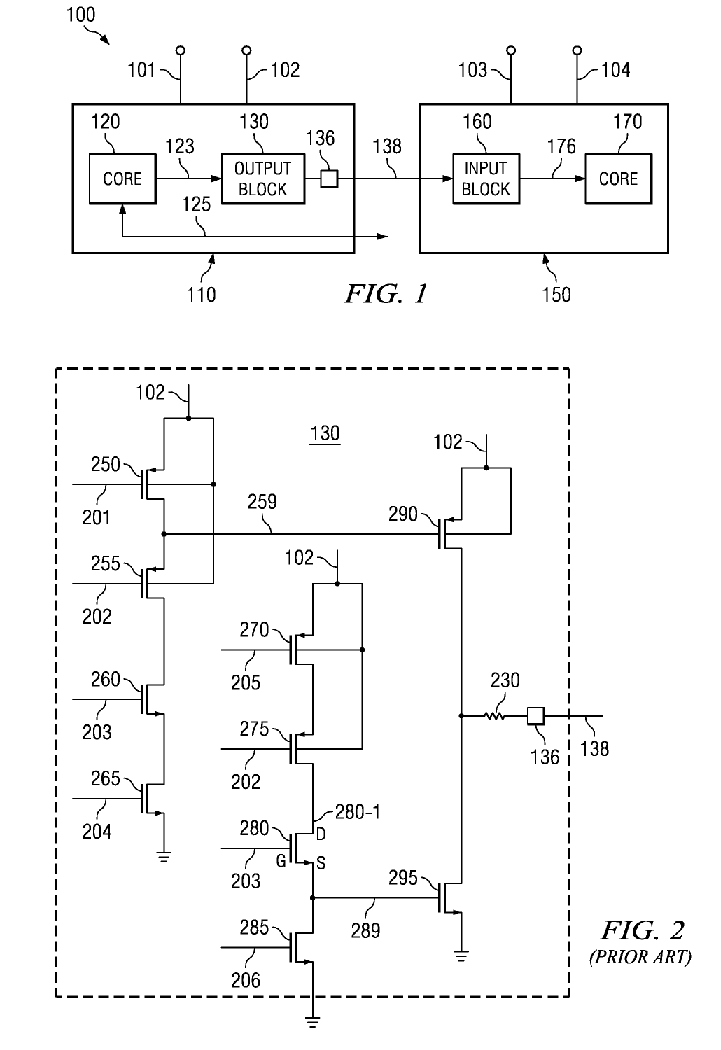

FIG. 1 is a block diagram of an example environment in which several aspects of the present invention can be implemented. System 100 is shown containing IC 110 and IC 150. For illustration, it is assumed that output block 130 of IC 110 is fabricated according to a 1.8V process (lower voltage process), while output signal 138 is to be provided at a 3.3 V level (higher voltage) and thus required to support higher voltage swing (0 to 3.3 V). Core 120 may be fabricated using a 1.2V process. IC 150 can be fabricated using 1.2V, 1.8V or 3.3V process.

It should be appreciated that 1.8V and 3.3V are merely examples of lower and higher voltages. However, several features of the present invention may be implemented with other combinations of voltage levels and processes, as will be apparent to one skilled in the relevant arts by reading the disclosure provided herein. The details of each IC is described below in further detail.

IC 110 is shown containing core 120 and output block 130. IC 150 is shown containing core 170 and input block 160.

IC 110 receives a 1.2V power supply via path 101, and a 3.3V power supply via path 102. The 1.2V power supply supplies power to core 120. Core 120 generates signals with a swing of 0-1.2V, and provides the signals to output block 130. Core 120 may correspond to a central processing unit (CPU), and may also provide/receive 0-1.2V signals on path 125 to/from other circuits not shown.

In an embodiment, the signal on each of the paths 123 and 138 represents a digital signal, with a voltage level of 0V representing one binary value and 1.2V representing the other binary value on path 123, and a voltage level of 0V representing one binary value and 3.3V representing the other binary value on path 138. Thus, the voltage on path 123 swings between 0V and 1.2V, while the voltage on path 138 swings between 0V and 3.3V.

Output block 130 receives 0-1.2V swing signals from core 120 via path 123, and forwards the received signals on path 138 (via IC pad 136) with a higher swing of 0-3.3V. Output block 130 contains components fabricated according to a lower-voltage process (1.8V process in this example), but designed to provide a higher output signal swing 0V-3.3V.

IC 150 receives a 1.2V power supply via path 104, and a 3.3V power supply via path 103. The 1.2 V power supply supplies power to core 170, as well as portions of input blocks 160. Input block 160 receives the higher swing 0-3.3V signals and forwards the signals as 0-1.2V on path 176 to core 170.

An aspect of the present invention enables output block 130 to be implemented with several advantages. The features of an example implementation will be clearer in comparison with a prior embodiment. Accordingly, a prior implementation of output block 130 is described next.

3. Prior Technique

FIG. 2 is a circuit diagram illustrating the details of a portion of an output block implemented according to a prior technique. Merely for ease of understanding, the prior technique is described with respect to FIG. 1. Prior output block 130 is shown containing P-channel MOS transistors 250, 255, 270, 275, and N-channel MOS transistors 260, 265, 280 and 285, P-channel drain enhanced MOS (DEMOS) transistor 290, N-channel DEMOS transistor 295, resistor 230 and pad 136.

Signals at nodes 201, 204, 205 and 206 are generated within output block 130 (corresponding generating circuits not shown) in response to a low-voltage (0-1.2VV) signal received on path 123 from core 120. Signals at nodes 202 and 203 contain fixed voltages derived from power supply 102 (3.3V), and have voltage values such that the corresponding MOS transistors (255, 260, 275 and 280) are always ON. Resistor 230 is provided for impedance matching. To simplify the following description, the gate (G), source (S) and drain (D) terminals of only NMOS 280 are marked.

The logical operation of the circuit of FIG. 2 is first described for the two output levels on pad 136 (path 138), and thereafter the specific voltage values required for proper operation, as well as problems associated with the prior technique are noted.

Logic High on Pad 136:

Signal 201 switches OFF PMOS transistor 250, signal 204 switches ON NMOS transistor 265, signal 205 switches OFF PMOS transistor 270, and signal 206 switches ON NMOS transistor 285. Consequently, DEMOS 290 is switched ON, while DEMOS 295 is switched OFF, and a logic high (approximately 3.3V) is present on pad 136.

b) Logic Low on Pad 136:

Signal 201 switches ON PMOS transistor 250, signal 204 switches OFF NMOS transistor 265, signal 205 switches ON PMOS transistor 270, and signal 206 switches OFF NMOS transistor 285. Consequently, DEMOS 290 is switched OFF, while DEMOS 295 is switched ON, and a logic low (approximately 0V) is present on pad 136.

Several problems associated with the prior circuit noted above are now described with respect to the state of the circuit of FIG. 2 when a logic low is provided on pad 136.

As noted above, to provide a logic low on pad 136, PMOS 270 is ON. As noted above, PMOS 275 is always ON. Consequently, voltage on drain terminal (280-1 in FIG. 2) of NMOS 280 is 3.3V. Since gate terminal (connected to path 289) of N-channel DEMOS 295 is a high-impedance node, NMOS 280 is just above cut-off, and the gate-to-source voltage Vgs of NMOS 280 is equal to Vt (threshold voltage).

Thus, voltage (V203) at node 203 should equal the sum of Vt and voltage (V289) on path 289,

i.e., V203=Vt+V289 Equation 1

Assuming that 1.8V must be applied on path 289 to reliably switch ON (and maintain ON) NMOS 295, equation 1 may be expressed as:

V203=Vt+1.8V Equation 2

Since, Vt is typically around 0.7V, from equation 2, V203 must have a value of 2.5V.

When NMOS 285 is ON, source terminal of NMOS 280 is at 0V. Therefore, a value of 2.5V on node 203 would cause the gate to source voltage (Vgs) of NMOS 280 to have a value of 2.5V. However, as noted above, NMOS 280 (as well as other components of FIG. 2) is fabricated according to a lower-voltage (1.8V in the example) process, and can reliably withstand a Vgs of only 1.8V. Thus, it may be seen that at least some components of the circuit of FIG. 2 may be subjected to voltages exceeding acceptable values.

Further, stray capacitance at the gate of N-channel DEMOS 295 may cause the voltage level on path 289 to change from 0V to 1.8V (or greater) very slowly. Consequently, another problem associated with the prior approach noted above is that the switching speed of the output 138 may be slow. While, the drawbacks noted above were made with respect to NMOS 280, similar problems associated with other components (such as PMOS 255) may also be present.

Several aspects of the present invention which overcome at least some of the drawbacks noted above are described next with respect to an example embodiment.

4. Novel Output Block in an Embodiment

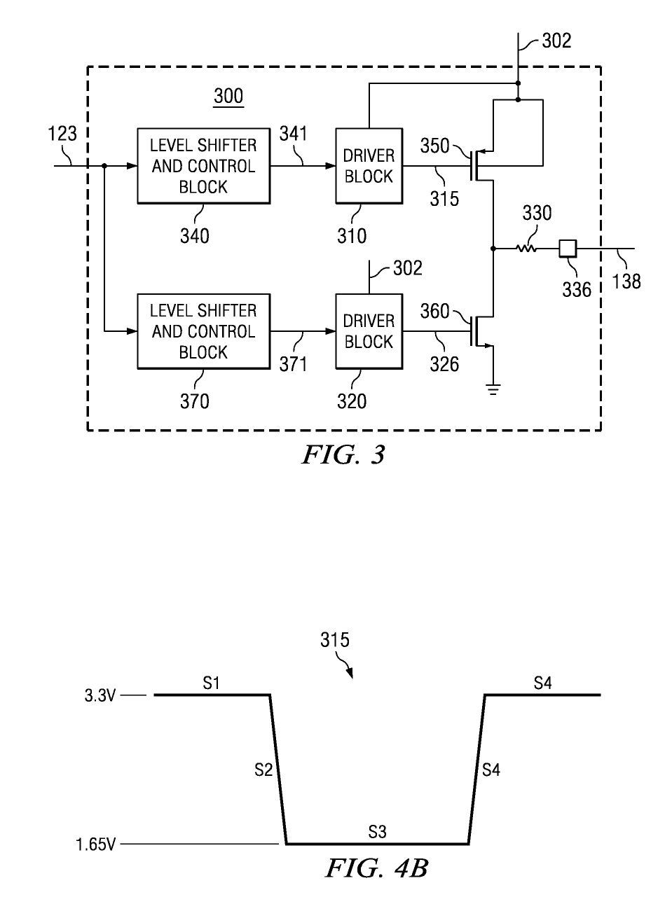

FIG. 3 is a block diagram of an output block in an embodiment of the present invention. Output block 300 is fabricated using a lower-voltage process (1.8V in the described embodiment), and provides output signals (on path 138) with a higher swing of 0V-3.3V. Output block 300 is shown containing level shifter and control blocks 340 and 370, driver blocks 310 and 320, P-channel DEMOS 350, N-channel DEMOS 360, resistor 330 and pad 336. Each block is described in detail below.

Level shifter and control block 340 receives on path 123 lower swing signals in the range 0-1.2V, and provides multiple signals (some being level-shifted to different voltage levels), as well as control signals to driver block 310 via path 341, as described in sections below. Similarly, level shifter and control block 370 receives on path 123 lower swing signals in the range 0-1.2V, and also provides multiple signals (some being level-shifted), as well as control signals to driver block 320 via path 371. Example embodiments of level shifter and control blocks 340 and 370 are described in detail in sections below.

Driver block 310, under control of level shifter and control block 340, generates signals on path 315 to switch P-channel DEMOS 350 ON or OFF depending on the required output level on pad 336. Similarly, driver block 320, under control of level shifter and control block 370, generates signals on path 326 to switch N-channel DEMOS 360 ON or OFF depending on the required output level on pad 336.

In particular, when a logic high (approximately 3.3V) is required on pad 336/path 138 (as response to input signal 123 being 1.2V) P-channel DEMOS 350 is switched ON, and N-channel DEMOS 360 is switched OFF by driver blocks 310 and 320 respectively. When a logic low (approximately 0V) is required on pad 336/path 138(as a response to input signal 123 being 0V), P-channel DEMOS 350 is switched OFF, and N-channel DEMOS 360 is switched ON by driver blocks 310 and 320 respectively.

Driver blocks 310 and 320, as well as level shifter and control blocks 340 and 370 operate in conjunction to provide the required voltage levels on path 138 in response to a voltage level on path 123. Driver blocks 310 and 320 can be constructed using substantially similar circuits. The details of a driver block 310 in an embodiment of the present invention are described in detail next.

5. Driver Block

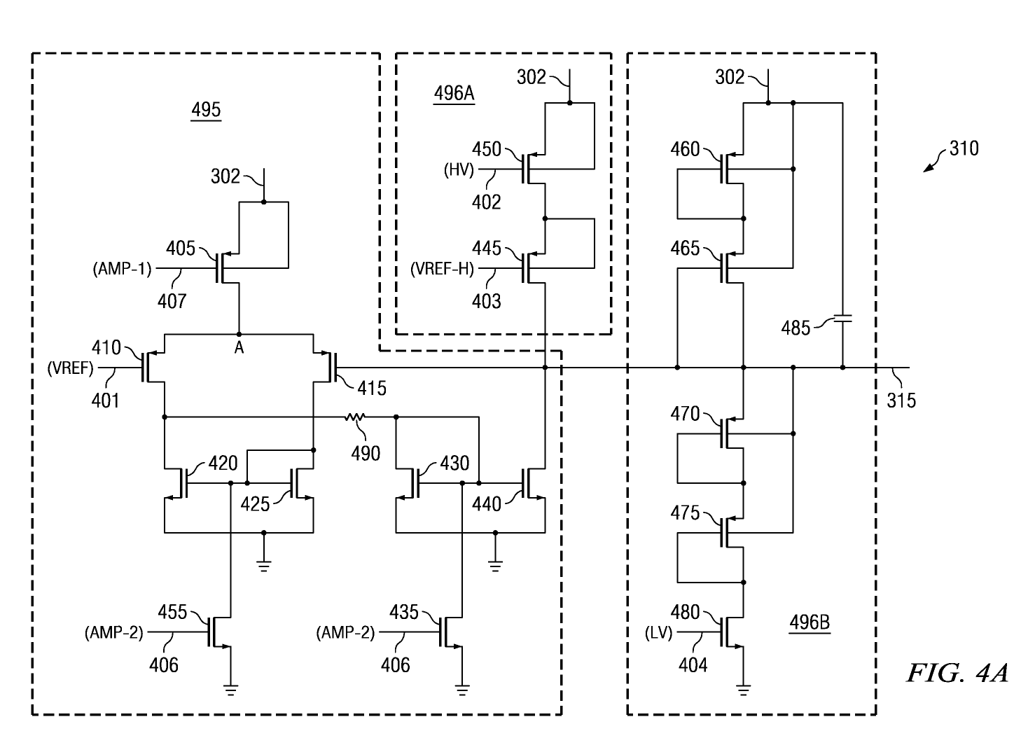

FIG. 4A is circuit diagram of driver block 310 in an embodiment of the present invention. Driver block 310 is shown containing P-channel DEMOS (drain enhanced MOS) transistors 410 and 415, N-channel DEMOS transistors 420, 425, 430, 440 and 480, PMOS transistors 445, 450, 460, 465, 470 and 475, NMOS transistors 435 and 455, and resistor 490. Terminal 302 receives a 3.3V power supply.

In FIG. 4A, signals on nodes 402 and 404 are level shifted signals generated in level shifter and control block 340 (FIG. 3) in response to a lower swing signal (0V-1.2V) received on path 123. When signal 123 is at 0V, node 402 receives 2.2V and node 404 receives 0V. When signal 123 is at 1.2V, node 402 receives 3.3V and node 404 receives 1.1V. For clarity, in the description below, signals having a range 0V-1.1V are in some instances referred to as NMOS domain signals, and signals having a range 2.2V-3.3V are referred to as PMOS domain signals.

Signals on nodes 406 and 407 are also generated in level shifter and control block 340 in response to a lower swing signal (0V-1.2V) received on path 123. Signal 407 is PMOS domain signal, while signal 406 is an NMOS domain signal. As noted above, nodes 402, 404, 406 and 407 are assumed to be contained in path 341 of FIG. 3.

In terms of operation, the circuit portion containing PMOS 445,450,460,465,475 and N-channel DEMOS 480 may be considered as a ‘hold’ circuit (containing hold circuit portions 496A and 496B as noted in FIG. 4A), while the circuit portion containing P-channel DEMOS transistors 410 and 415, N-channel DEMOS transistors 420, 425, 430 and 440, NMOS 435 and 455, and resistor 490 may be considered as a differential amplifier portion (marked as 495 in FIG. 4A). Voltage at node 403 (VREF-H) is a fixed voltage at a value (e.g., 2.2V) which maintains PMOS 445 in an ON state. Voltage at node 401 (VREF) is maintained constant at 1.65V. VREF and VREF-H may be generated by a voltage reference internal to output block 300, but not shown.

The operation of driver block 310 will be described with respect to the waveform of FIG. 4B, in which signal levels of signal 315 required to switch P-channel DEMOS 350 (FIG. 3) ON/OFF are shown. To simplify the following description, signal levels of signal 315 are associated with the following states:

S1—node 315 is at 3.3V (signal 123 is at 0V).

S2—node 315 is transitioning from 3.3V to VREF (voltage at node 401) in response to signal 123 transitioning from 0V to 1.2V.

S3—node 315 is at VREF (signal 123 is at 1.2V).

S4—node 315 is transitioning from VREF to 3.3V, or is at 3.3V (input 123 transitions from 1.2V to 0V).

It should be appreciated that Vref at a voltage of 1.65 volts is slightly less than 1.8 V (the process voltage used to fabricate output block 300), but much greater than 1.2 V (the process voltage of core 120). In other words, voltage Vref is much closer to 1.8 V than to 1.2 V. The specific value of Vref here is chosen to equal half of the voltage at power supply 302.

The operation of driver block 310 is described next for each of the four states noted above. It must be understood that voltage values (such as 3.3V, 1.8V etc) need not take on those exact values for proper operation of the circuit, but generally may be allowed to vary within acceptable limits, while still ensuring the operation described.

State S1:

Node 407(Amp-1) is held at 3.3V, node 406 is held at 1.1V, and consequently differential amplifier 495 is OFF (i.e., all of the constituent transistors in differential amplifier 495 are OFF, except NMOS 455 and 435). Node 404 (LV) is held at 0V, and hold circuit 496B is OFF (i.e., all of the constituent transistors in hold circuit 496B are OFF).

Node 402 (HV) is held at ⅔ times the strength (3.3V) of power supply 302, i.e at 2.2V, thereby turning ON PMOS 450. Since PMOS 445 is always ON, voltage at node 315 is 3.3V. Referring to FIG. 3, a voltage of 3.3V on path 315 switches OFF P-channel DEMOS 350, as required for a logic low (0V) on pad 336 (assuming also that N-channel DEMOS 360 is in the ON state.

Thus, during S1, differential amplifier 495 and hold circuit portion 496B are OFF. Hold circuit portion 496A holds the voltage at node 315 strongly at a 3.3V.

State S2:

Hold circuit portions 496A and 496B are switched OFF by applying 3.3V at node 402 (HV) and 1.1V at node 404 (LV) respectively. Substantially simultaneously, the voltage at node 407 (Amp-1) is changed from 3.3V to 2.2V, and the voltage at node 406 (Amp-2) is made 0V.

Consequently, voltage at node A is 3.3V. Since node 315 was previously (end of S1) at 3.3V, P-channel DEMOS 415 is OFF. Since P-channel DEMOS is OFF, N-channel DEMOS 425 is also OFF. Since N-channel DEMOS 420 and 425 constitute a current mirror pair, N-channel DEMOS 420 is also OFF. However, P-channel DEMOS 410 is ON due to the 1.65V at node 401 (VREF).

As a result, current flows through P-channel DEMOS 410, resistor 490 and the circuit formed by N-channel DEMOS 430 and 440. Therefore, the 3.3V present previously (end of S1) at node 315 begins to decrease.

When the voltage at node 315 decreases to a sufficiently low value, P-channel DEMOS 415 is switched ON. Consequently, N-channel DEMOS 420 and 425 are also turned ON. A steady state is reached when voltage node 315 equals the fixed voltage at node 401 (VREF), i.e., 1.65V. When voltage at node 315 falls to 1.65V, current flow through resistor 490 and the circuit formed by N-channel DEMOS 430 and 440 becomes zero, and node 315 is held steady at 1.65V.

Referring now to FIG. 3, a voltage of about 1.65V on path 315 is sufficient to switch ON P-channel DEMOS 350, as required for a logic high (3.3V) on pad 336 (assuming also that N-channel DEMOS 360 is in the OFF state). Since differential amplifier 495 is a high current device, the transition at node 315 from 3.3V to 1.65V may be effected at a high speed.

When voltage at node 315 decreases to about 1.65V, corresponding circuitry (described below) in level shifter and control block 340 drives the voltages at node 407 and 406 to 3.3V and 0V respectively, thereby switching OFF differential amplifier 495. Substantially simultaneously, the circuit of FIG. 4A enters state 3.

State 3:

Voltage at node 404 (LV) is held at 1.1V (⅓ times the power supply voltage 3.3V). Hold circuit portion 496A continues to remain OFF by application of 3.3V at node 402 (HV). Differential amplifier 495 is also OFF.

Hold circuit portion 496B acts a voltage divider, and maintains node 315 at 1.65V (established at state S2 noted above).

It may now be apparent that the switch from S1 to S2 is accomplished by differential amplifier, which enables a fast transition to S2. Once state S2 is reached (i.e., node 315 reaches 1.8V), differential amplifier 395 is turned OFF, and state S2 is maintained by hold circuit portion 396B, which is designed to consume very little power during operation.

State S4:

Hold circuit portion 496A is switched ON by applying 2.2V at node 402 (HV). Substantially simultaneously, hold circuit portion 496B is switched OFF by applying 0V at node 404 (LV). Differential amplifier 495 continues to remain OFF.

Hold circuit portion 496A quickly pulls node 315 to 3.3V. Referring to FIG. 3, a voltage of 3.3V on path 315 switches OFF P-channel DEMOS 350, as required for a logic low (0V) on pad 336 (assuming also that N-channel DEMOS 360 is in the ON state.

Thus, switching between logic states (at pad 336) is accomplished by a high current device, viz., differential amplifier 495, and provides fast switching speeds. Steady states are maintained by hold circuits 496A and 496B which are low current (low power) circuits. Therefore, overall high-speed circuit operation is accomplished with relatively low power consumption.

It may also be observed that no component of driver block 310 is subjected to excessive voltages across any terminal pairs. In contrast, it was noted above that components such as NMOS 280 of the prior technique (FIG. 2) were subjected to voltages exceeding acceptable levels at leas during some portion of their operation.

Resistor 490 is used to limit the current flowing through current mirror 430/440. NMOS 435 and 455 are used to maintain the gate terminals of N-channel DEMOS 420, 425, 430 and 440 in a known state (0V), by application of 1.1V at node 406 (Amp-2). Capacitor 485 prevent/minimizes fluctuations/noise on node 315 from affecting PMOS 350 and 465, by coupling the fluctuations to the power supply terminal 302.

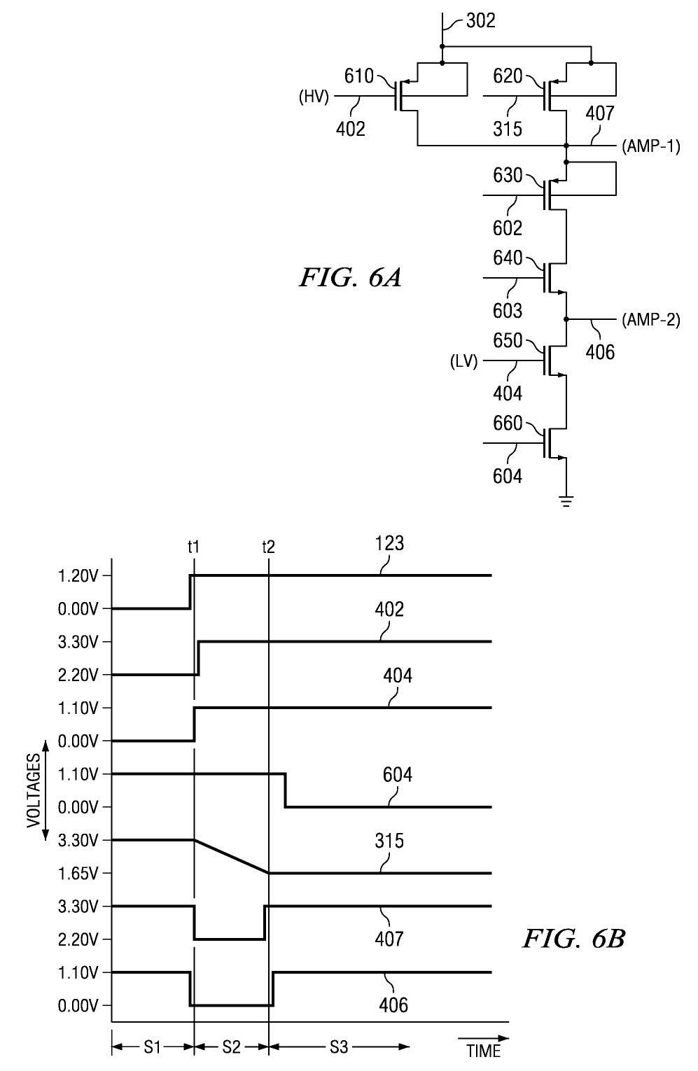

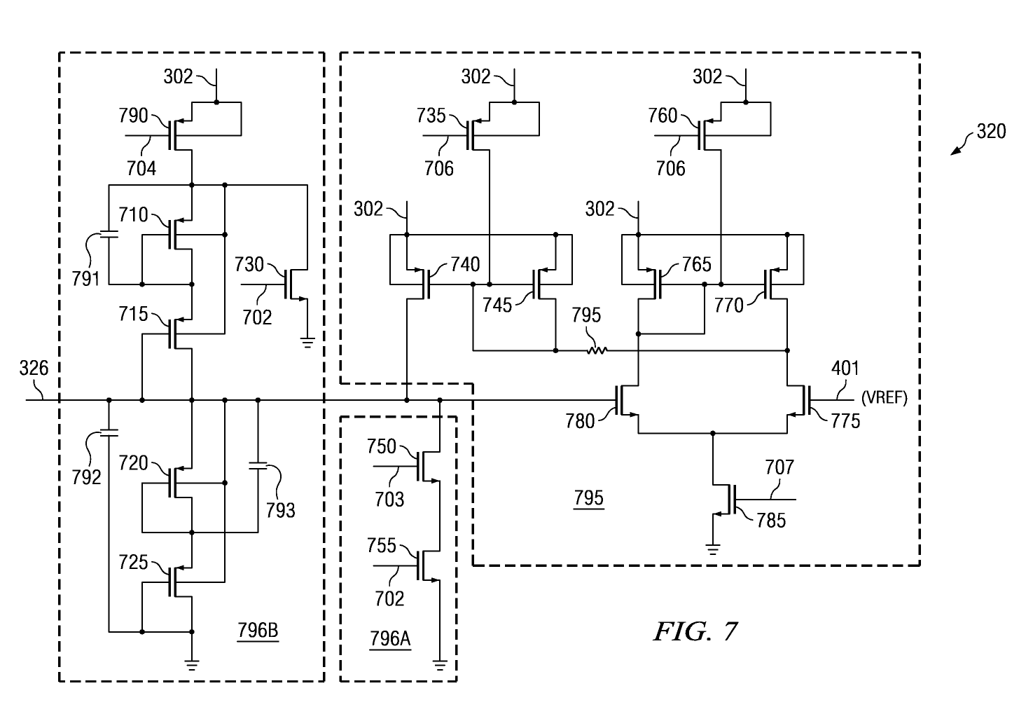

The circuitry and operation of driver block 320 is substantially similar to that of driver block 310, and is briefly described below with respect to FIGS. 6 and 7. Output block 300 may be used in IC 110 in place of output block 130. IC 110 containing output block 300 fabricated according to a lower-voltage (1.8V) process may thus provide signals with higher signal swings 0-3.3V, with both higher switching speeds and increased reliability.

The description is continued with an illustration with respect to a flowchart of the manner in which the operation of output block 300 is effected.

6. Control

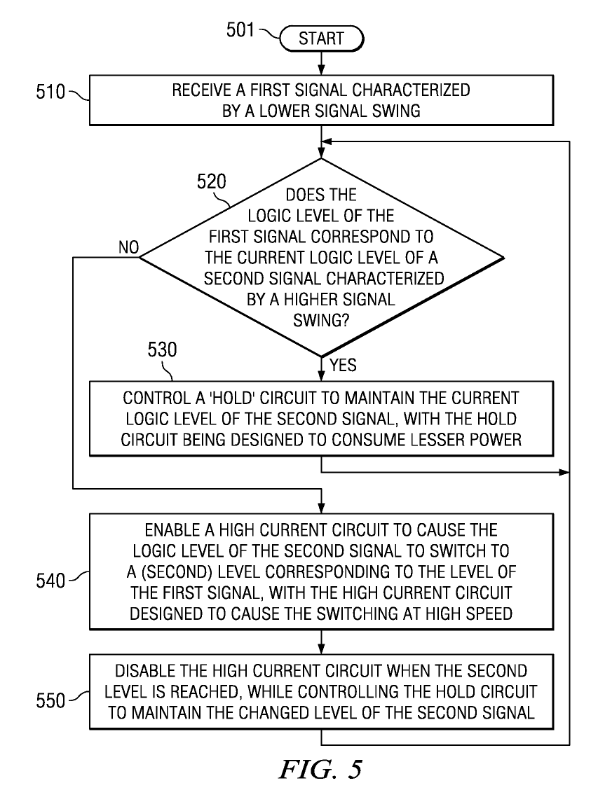

FIG. 5 is a flowchart illustrating the manner in which an output block implemented according to aspects of the present invention may be controlled to operate as described above.

The flowchart is described with respect to FIG. 3, and in relation to the components of level shifter and control block 340, merely for illustration. However, various features can be implemented in other environments and other components. Furthermore, the steps are described in a specific sequence merely for illustration.

Alternative embodiments in other environments, using other components and different sequence of steps can also be implemented without departing from the scope and spirit of several aspects of the present invention, as will be apparent to one skilled in the relevant arts by reading the disclosure provided herein. The flowchart starts in step 501, in which control passes immediately to step 510.

In step 510, level shifter and control block 340 receives a first signal characterized by a lower signal swing. The first signal may have a signal swing of, for example, 0V to 1.2V. Control then passes to step 520.

In step 520, level shifter and control block 340 determines if the logic level of the first signal corresponds to the current logic level of a second signal characterized by a higher signal swing. Thus, for instance, if the second signal is to be provided as a non-inverted version of the first signal, level shifter and control block 340 may determine if the current logic level (high or low) of the second signal is the same as the logic level of the first signal. If the signal levels correspond, control passes to step 530, else control passes to step 540.

In step 530, level shifter and control block 340 controls a ‘hold’ circuit to maintain the current logic level of the second signal. The hold circuit is designed to consume lesser power during operation. Control then passes to step 540, in which level shifter and control block 340 continues to determine if the logic levels of the first and second signals correspond.

In step 540, level shifter and control block 340 enables a high current circuit to cause the logic level of the second signal to switch to a level corresponding to the level of the first signal, with the high current circuit designed to cause the switching at a fast rate. During the operation of this step, the level shifter and control block 340 may disable the hold circuit. Control then passes to step 550.

In step 550, level shifter and control block 340 disables the high current circuit, while controlling the hold circuit to maintain the changed level of the second signal. Thus, level shifter and control block 340 achieves switching using a high-speed/high power circuit, but uses a low-power hold circuit once switching is over. Control then passes to step 520.

It may be noted that steps 530, 540 and 550 substantially correspond to states S1 , S2 and S3 described above. An embodiment of level shifter and control block 340 is described next.

7. Level shifter and control block

FIG. 6A is a block diagram illustrating partial internal details of level shifter and control block 340. The diagram is shown containing PMOS transistors 610, 620 and 630, and NMOS transistors 640, 650 and 660. The operation of the circuit shown in the Figure is described below with combined reference to the timing diagram of FIG. 6B.

Nodes 602 is permanently held at 1.6V (2.2V+Vtp, wherein Vtp is the threshold voltage of a PMOS transistor (−0.6V) used in output block 300), and node 603 is permanently held at 1.7V (1.1V+Vtn, wherein Vtn is the threshold voltage of an NMOS transistor used in output block 300) by respective voltage references (not shown) obtained from power supply 302 by a voltage divider network contained in output block 300. As result. Both PMOS 630 and NMOS 640 are always in the ON state.

As noted above, signals at node 402 (HV), 404 (LV) and 604 are generated in response to lower swing signal received as input (on path 123 of FIG. 3) by a level shifting circuit (not shown) contained in level shifter and control block 340, and contain voltages at various instances according to one of states S1 through S4 noted above. Signal at node 604 is a delayed signal (with respect to signal 404) generated within level shifter and control block 340, has a phase opposite to that of signal 404 (LV)and has range from 0V to 1.1V.

FIG. 6B is a timing diagram illustrating voltage levels at the respective nodes for a scenario of input signal 123 changing from a logic low to logic high.

In operation, during state S1, input signal 123 is at 0V. Therefore, node 402 is at 2.2V and PMOS 610 is switched ON. Node 404 (LV) is at 0V, and NMOS 650 is OFF. Consequently, nodes 407 (Amp-1) is at 3.3V, and node 406 (Amp-2) is at 1.1V as required. Node 315 is at 3.3V.

During state S2, at time instance t1, input signal 123 transitions from 0V to 1.2V. As a result, node 402 transitions to 3.3V and switches off PMOS 610. Node 315 is also at 3.3V. However, since nodes 404 and 604 are high, NMOS 650 and 660 are enabled, and node 407 transitions to 2.2V. With respect to FIG. 4A, node 407 transitioning to 2.2V switches ON differential amplifier 495, and differential amplifier 495 operates to bring node 315 to 1.65V (at time instance t2 in FIG. 6B) as described above.

As noted above, signal 604 is an NMOS level signal which is anti-phase to 404 and delayed in time. Therefore, signal 604 transitions to 0V after a predetermined delay after signal 404 goes to 1.1V. The predetermined delay is selected to be sufficiently long to enable differential amplifier 495 to pull node 315 from 3.3V to 1.65V in a manner described above.

During state S3, input signal 123 is at 1.2V, node 402 is at 3.3V. However, node 315 is at 1.65V. As a result, PMOS 620 is ON, and node 407 is at 3.3V, thereby switching OFF differential amplifier 495, as required. Also during S3, node 404 is at 1.1V, NMOS 650 is ON. Consequently, node 406 is at 1.1V, also as required. Operation of the circuit of FIG. 6A during state S4 is similar to that during state S1 described above.

In the embodiment described with respect to FIG. 3, driver block 320 is implemented to have a substantially similar structure as driver block 310. Hence, the detailed operation will not be described in the interest of conciseness. Instead, only the circuit structure and similarities with respect to driver block 310 are briefly noted next.

FIG. 7 is circuit diagram of driver block 320 in an embodiment of the present invention. Driver block 320 operates to drive (hold) node 326 to 1.65V when input signal 123 is at 0V, and drive node 326 to 0V when input signal 123 is at 1.2V.

In terms of operation, the circuit portion containing PMOS 710, 715, 720, 725, P-channel DEMOS 790, NMOS 750 and 755 may be considered as a ‘hold’ circuit (containing hold circuit portions 796A and 796B as noted in FIG. 7), while the circuit portion containing P-channel DEMOS transistors 740, 745, 765, 770, N-channel DEMOS transistors 775 and 780, PMOS 735 and 760, and resistor 795 may be considered as a differential amplifier portion (marked as 795 in FIG. 4A).

Voltage at node 703 (VREF-H) is a fixed voltage at a value (e.g., 1.1V) which maintains NMOS 750 in an ON state, and may be generated by a voltage reference internal to output block 300.

Voltage at node 326 has the following levels with respect to states S1-S4 noted above:

S1—node 326 is at 1.65V.

S2—node 326 is transitioning from 1.65V to 0V.

S3—node 326 is at 0V.

S4—node 326 is transitioning from to 0V to 1.65V, or is at 1.65V.

In terms of operation, differential amplifier 795 operates substantially similarly to differential amplifier 395 of driver block 310. Similarly, hold circuit portions 796A and 796B operate substantially similarly to hold circuit portions 496A and 496B.

FIG. 8 is a circuit diagram of level shifter and control block 370. Level shifter and control block 370 operates substantially similarly to level shifter and control block 340, and the detailed operation will not be described in the interest of conciseness.

Level shifter and control block 370 is shown containing PMOS transistors 810, 820 and 830, and NMOS transistors 840, 850 and 860. Nodes 602 and 603 are permanently held at 1.6V and 1.7V respectively by a voltage reference (not shown) contained in output block 300, thereby permanently switching ON PMOS 830 and NMOS 840. Voltages at node 702, 704 and 801 may be generated by a level shifting circuit (not shown) contained in level shifter and control block 370, and have values at various instances according to one of states S1 through S4, in a manner similar to that noted above with respect to level shifter and control block 340. Voltage at node 702 represents a delayed signal generated within level shifter and control block 370, and has range from 0V to 1.1V. Voltages at nodes 704 and 801 have a range of 2.2V to 3.3V. Signal 707 has a range of 0V-1.1V, and signal 706 has a range of 2.2-3.3V.

IC 110 implemented using output block 300 provides output signals with higher swing with faster switching speeds and has better reliability. IC 110 may be incorporated in a device or system, as described next with an example.

8. Device/System

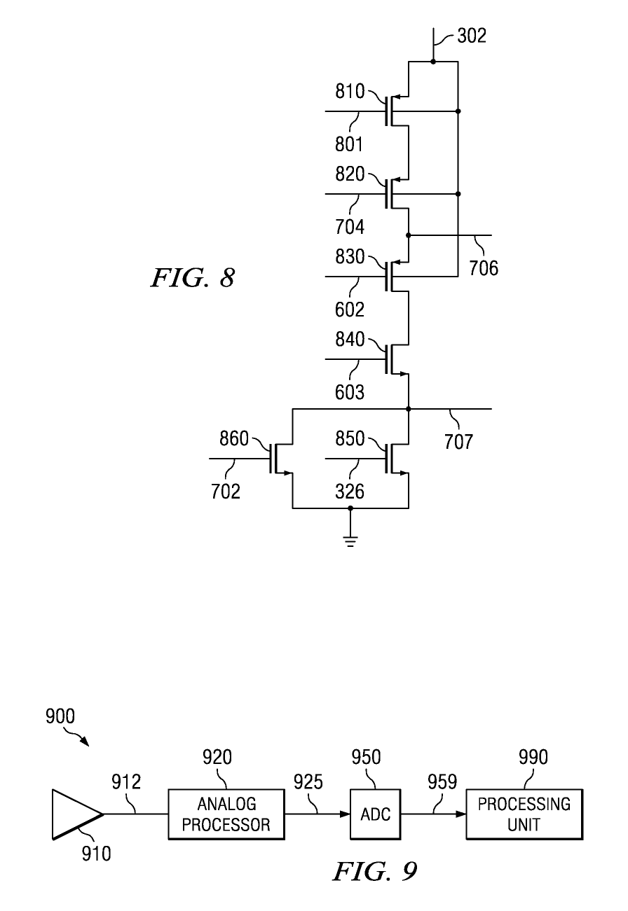

FIG. 9 is a block diagram of receiver system 900 illustrating an example system in which the present invention may be implemented. Receiver system 900, which may correspond to, for example, a mobile phone is shown containing antenna 910, analog processor 920, ADC 950, and processing unit 990. Each component is described in further detail below.

Antenna 910 may receive various signals transmitted over a wireless medium. The received signals may be provided to analog processor 920 on path 912 for further processing. Analog processor 920 may perform tasks such as amplification (or attenuation as desired), filtering, frequency conversion, etc., on received signals and provides the resulting signal on path 925.

ADC 950 converts the analog signal received on path 925 to corresponding digital codes, and provides the digital codes to processing unit 990 on path 959 for further processing.

Processing unit 990 receives the recovered data to provide various user applications (such as telephone calls, data applications), and contains an output block, implemented as described above, to provide output signals with a higher voltage swing.

7. Conclusion

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. An output block receiving an input signal with a first voltage swing and providing an output at a second voltage swing, wherein said first voltage swing is lower than said second voltage swing, said input signal being either at a first logic level or a second logic level, said output block being fabricated using a process tailored for a voltage level less than said second voltage swing, said output block comprising:
a pair of drain enhanced transistors having a conducting path from a high voltage reference to a constant bias terminal when both are turned on, said output being provided at a junction connecting a respective drain terminal of said pair of drain enhanced transistors, each of said pair of drain enhanced transistors having a control terminal which switches off the drain enhanced terminal when at one voltage level at the control terminal and switches on the drain enhanced terminal at another voltage level, said pair of drain enhanced transistors containing a first transistor and a second transistor;
a differential amplifier to control the voltage level at the control terminal of said first transistor, said differential amplifier operating to quickly pull said voltage level at said control terminal from a high voltage level to a low voltage level when on, and being electrically isolated from said control terminal otherwise;
a hold circuit block to maintain said control terminal of said first transistor at said low voltage level when said differential amplifier is switched off and said input signal is at one of said first logic level and said second logic level, said hold circuit block to maintain said control terminal of said first transistor at said high voltage level when said differential amplifier is switched off and said input signal is at the other one of said first logic level and said second logic level; and
a control block to switch on said differential amplifier when said input signal transitions from said first logic level to said other one of said first logic level and said second logic level.

2. The output block of claim 1, wherein said output block is fabricated using a process tailored for a third voltage level which is less than said second voltage swing and greater than said first voltage swing, wherein said low voltage level is slightly less than said third voltage level and much greater than said first voltage swing, said output block further comprising:
a level shifter to generate a first level shifted signal and a second level shifted signal, said first level shifted signal being at a first voltage level and said second level shifted signal being at a second voltage level if said input signal is at said first logic level, said first level shifted signal being at a third voltage level and said second level shifted signal being at a fourth voltage level if said input signal is at said second logic level,
wherein said first level shifted signal controls said hold circuit block to maintain said control terminal of said first transistor at said low voltage level, and
wherein said second level shifted signal controls said hold circuit block to maintain said control terminal of said first transistor at said high voltage level.

3. The output block of claim 2, wherein said hold circuit block comprises a third drain enhanced transistor providing a conductive path from said control terminal to said constant bias terminal when turned on,
wherein said first level shifted signal switches on said third drain enhanced transistor to maintain said control terminal of said first transistor at said low voltage level.

4. The output block of claim 3, wherein said hold circuit block comprises a fourth transistor providing a conductive path from said control terminal to said high voltage reference when turned on,
wherein said second level shifted signal switches on said fourth transistor to maintain said control terminal of said first transistor at said high voltage level.

5. The output block of claim 4, wherein said differential amplifier contains a second control terminal which when at a low voltage level turns on said differential amplifier to pull said control terminal to said low voltage level.

6. The output block of claim 1, further comprising a second differential amplifier, a second hold circuit and a second control block which respectively operate similar to said differential amplifier, said hold circuit block and said control block, and operate to control the logic level at the control terminal of said second transistor.

7. An integrated circuit (IC), said IC comprising:
A core portion generating a signal with a first voltage swing; and
an output block receiving said signal and providing an output at a second voltage swing, wherein said first voltage swing is lower than said second voltage swing, said signal being either at a first logic level or a second logic level, said output block being fabricated using a process tailored for a voltage level less than said second voltage swing, said output block comprising:
a pair of drain enhanced transistors having a conducting path from a high voltage reference to a constant bias terminal when both are turned on, said output being provided at a junction connecting a respective drain terminal of said pair of drain enhanced transistors, each of said drain enhanced transistors having a control terminal which switches off the drain enhanced terminal when at one voltage level at the control terminal and switches on the drain enhanced terminal at another voltage level, said pair of drain enhanced transistors containing a first transistor and a second transistor;
a differential amplifier to control the voltage level at the control terminal of said first transistor, said differential amplifier operating to quickly pull said voltage level at said control terminal from a high voltage level to a low voltage level when on, and being electrically isolated from said control terminal otherwise;
a hold circuit block to maintain said control terminal of said first transistor at said low voltage level when said differential amplifier is switched off and said input signal is at one of said first logic level and said second logic level, said hold circuit block to maintain said control terminal of said first transistor at said high voltage level when said differential amplifier is switched off and said input signal is at the other one of said first logic level and said second logic level; and
a control block to switch on said differential amplifier when said input signal transitions from said first logic level to said other one of said first logic level and said second logic level.

8. The IC of claim 7, wherein said output block is fabricated using a process tailored for a third voltage level which is less than said second voltage swing and greater than said first voltage swing, wherein said low voltage level is slightly less than said third voltage level and much greater than said first voltage swing, said output block further comprising:
a level shifter to generate a first level shifted signal and a second level shifted signal, said first level shifted signal being at a first voltage level and said second level shifted signal being at a second voltage level if said input signal is at said first logic level, said first level shifted signal being at a third voltage level and said second level shifted signal being at a fourth voltage level if said input signal is at said second logic level,
wherein said first level shifted signal controls said hold circuit block to maintain said control terminal of said first transistor at said low voltage level, and
wherein said second level shifted signal controls said hold circuit block to maintain said control terminal of said first transistor at said high voltage level.

9. The IC of claim 8, wherein said hold circuit block comprises a third drain enhanced transistor providing a conductive path from said control terminal to said constant bias terminal when turned on,
wherein said first level shifted signal switches on said third drain enhanced transistor to maintain said control terminal of said first transistor at said low voltage level.

10. The IC of claim 9, wherein said hold circuit block comprises a fourth transistor providing a conductive path from said control terminal to said high voltage reference when turned on,
wherein said second level shifted signal switches on said fourth transistor to maintain said control terminal of said first transistor at said high voltage level.

11. The output block of claim 10, wherein said differential amplifier contains a second control terminal which when at a low voltage level turns on said differential amplifier to pull said first control terminal to said low voltage level.

12. The IC of claim 7, wherein said output block further comprises a second differential amplifier, a second hold circuit and a second control block which respectively operate similar to said differential amplifier, said hold circuit block and said control block, and operate to control the logic level at the control terminal of said second transistor.
